(19) United States
(12) Patent Application Publication
(10) Pub. No.: US 2010/0082277 A1
(43) Pub. Date: Apr. 1, 2010

(54) DISTRIBUTED CAR CHARGING MANAGEMENT SYSTEM AND METHOD

(76) Inventor: Claudio R. Ballard, Fort Lauderdale, FL (US)

Correspondence Address: HOWISON & ARNOTT, L.L.P, P.O. BOX 741715, DALLAS, TX, 75374-1715, US

(21) Appl. No.: 12/570,884

(22) Filed: Sep. 30, 2009

Related U.S. Application Data
(60) Provisional application No. 61/101,550, filed on Sep. 30, 2008.

(51) Int. Cl. G01R 31/36; G06F 19/00

(52) U.S. Cl. 702/63; 701/22; 180/65.29

(57) ABSTRACT

A power control system positioned within a car is provided. In one example, the power control system includes an electrical system, a battery and a power interface coupled to the electrical system, a communication interface, a controller coupled to the electrical system and the communication interface, and a memory coupled to the controller. The memory contains instructions executable by the controller. The instructions include receiving at least one power consumption parameter from a power controller external to the car via the communication interface, actuating the electrical system to access an external power source via the power interface, and directing power from the power source to the battery via the electrical system in order to charge the battery. One or both of actuating the electrical system to access the external power source and an amount of power directed to the battery are based on the power consumption parameter.

### CROSS-REFERENCE TO RELATED APPLICATIONS

This application claims the benefit of U.S. provisional application for patent Ser. No. 61/101,550, filed Sep. 30, 2008, and entitled DISTRIBUTED CAR CHARGING MANAGEMENT SYSTEM AND METHOD (VMDS-29,060).

### TECHNICAL FIELD

The following disclosure relates to power distribution systems and, more particularly, to the intelligent distribution of power to vehicles over an electrical grid.

### BACKGROUND

It is well known that power distribution over an electrical grid, such as a grid supplying power to residences and businesses, is a complicated process. Component failures, unanticipated demand for electricity due to weather changes, the increasing load due to modern electronics, and other technical issues make grid management an increasingly complex balance of supply and demand. However, although modern grids may use a certain level of power scheduling, such scheduling tends to be relatively static and so inefficiencies exist in grid management. Therefore, a need exists for a system that is able to manage the provision of power to distributed destinations across a power grid.

### SUMMARY

In one embodiment, a power control system positioned within a car is provided. The power control system comprises an electrical system, a battery coupled to the electrical system, a power interface coupled to the electrical system, a communication interface, a controller coupled to the electrical system and the communication interface, and a memory coupled to the controller and containing a plurality of instructions executable by the controller. The instructions include instructions for receiving at least one power consumption parameter from a power controller external to the car via the communication interface, actuating the electrical system to access an external power source via the power interface, and directing power from the power source to the battery via the electrical system in order to charge the battery. At least one of actuating the electrical system to access the external power source and an amount of power directed to the battery is based on the at least one power consumption parameter.

In another embodiment, the instructions further comprise instructions for determining a charge level of the battery while power is being directed from the external power source to the battery.

In another embodiment, the power control system further comprises a power profile stored in the memory, wherein the power profile includes information about power usage by the car.

In another embodiment, the at least one power consumption parameter is stored by the controller as part of the power profile.

In another embodiment, the power control system further comprises a power profile stored in the memory, wherein the power profile includes information about at least one power need of the car that is based on an amount of power needed by the battery.

In another embodiment, the power profile further includes information defining a time window during which the car is available to access the external power source.

In another embodiment, the power control system further comprises instructions for sending the information about the at least one power need and the time window to the power controller via the communication interface.

In another embodiment, the sending occurs after the car is coupled to the external power source.

In another embodiment, the sending occurs before the car is coupled to the external power source.

In another embodiment, the at least one power consumption parameter defines a start time representing an earliest time at which the car is to access the external power source.

In another embodiment, the at least one power consumption parameter further defines an end time representing a latest time at which the car is to access the external power source.

In another embodiment, the at least one power consumption parameter further defines a power bandwidth representing a peak power draw to be used by the car when accessing the external power source.

In another embodiment, the power control system further comprises instructions for sending a compliance notification via the communication interface, wherein the compliance notification confirms that the battery was charged based on the at least one power consumption parameter.

In another embodiment, the power control system further comprises instructions for sending a notification to the power controller that the car has finished charging.

In another embodiment, the power control system further comprises instructions for overriding the at least one power consumption parameter.

In another embodiment, the power control system further comprises instructions for sending identification information to the power controller, wherein the identification information represents at least one of a unique identity and a location of the car.

In a further embodiment, a power controller for managing power consumption by a car coupled to a power grid is provided. The power controller comprises a communication interface, a processor coupled to the communication interface, and a memory coupled to the processor and containing a plurality of instructions executable by the processor. The instructions include instructions for receiving power need information from the car, wherein the power need information identifies an amount of power needed in charging a battery of the car, and identifying a power consumption need for each of a plurality of power consumers. The instructions also include determining a power consumption plan defining at least one of a start time and a power bandwidth for the car in response to receiving the power need information, wherein at least one of the start time and the power bandwidth is calculated based on the power need information of the car and the power consumption needs of the plurality of power consumers. The instructions further include sending the power consumption plan to the car to manage the car's power consumption from the grid.

In another embodiment, receiving the power need information from the car includes receiving at least a portion of a profile defining power usage requirements of the car.

In another embodiment, receiving the power need information from the car includes receiving at least a portion of a profile defining a power usage history of the car.

In another embodiment, receiving the power need information from the car includes receiving a start time and an end time, wherein the start time and end time define an earliest time and a latest time, respectively, that the car is available for power consumption from the grid.

In another embodiment, the power controller further comprises instructions for determining that the car has complied with the power consumption plan.

In another embodiment, the power controller further comprises applying a discounted rate to electricity supplied to the car via the grid after determining that the car has complied with the power consumption plan.

In still another embodiment, a method for use in a car is provided. The method comprises determining power need information of a battery of the car, sending the power need information to a power controller external to the car, receiving a power consumption plan from the power controller, wherein the power consumption plan defines at least one of a start time parameter and a power bandwidth parameter for use in charging the battery, determining whether an override is active; and accessing a power source to charge the battery based on the power consumption plan unless the override is active, wherein the override negates at least a portion of the power consumption plan.

### BRIEF DESCRIPTION OF THE DRAWINGS

For a more complete understanding, reference is now made to the following description taken in conjunction with the accompanying Drawings in which:

FIG. 1 illustrates one embodiment of a distributed car charging environment;

FIG. 2 illustrates one embodiment of a power control system that may be used in the environment of FIG. 1;

FIG. 3 illustrates one embodiment of a power profile that may be used with the power control system of FIG. 2;

FIG. 4 illustrates another embodiment of a power control system that may be used in the environment of FIG. 1;

FIG. 5 is a sequence diagram illustrating one embodiment of a sequence of actions that may occur to schedule battery charging for multiple distributed power consumers;

FIG. 6 is a sequence diagram illustrating one embodiment of a sequence of actions that may occur to provide feedback during or after battery charging in an environment with multiple distributed power consumers;

FIG. 7 illustrates one embodiment of an environment in which information relative to power consumption by a power access point and/or a power consumer may be used;

FIG. 8 is a flow chart illustrating one embodiment of a method by which a power consumer may obtain one or more power consumption parameters; and

FIG. 9 is a flow chart illustrating one embodiment of a method by which a power controller may manage power consumption by a power consumer.

### DETAILED DESCRIPTION

Referring now to the drawings, wherein like reference numbers are used herein to designate like elements throughout, the various views and embodiments of systems and methods for managing distributed power are illustrated and described, and other possible embodiments are described. The figures are not necessarily drawn to scale, and in some instances the drawings have been exaggerated and/or simplified for illustrative purposes only. One of ordinary skill in the art will appreciate the many possible applications and variations based on the following examples of possible embodiments.

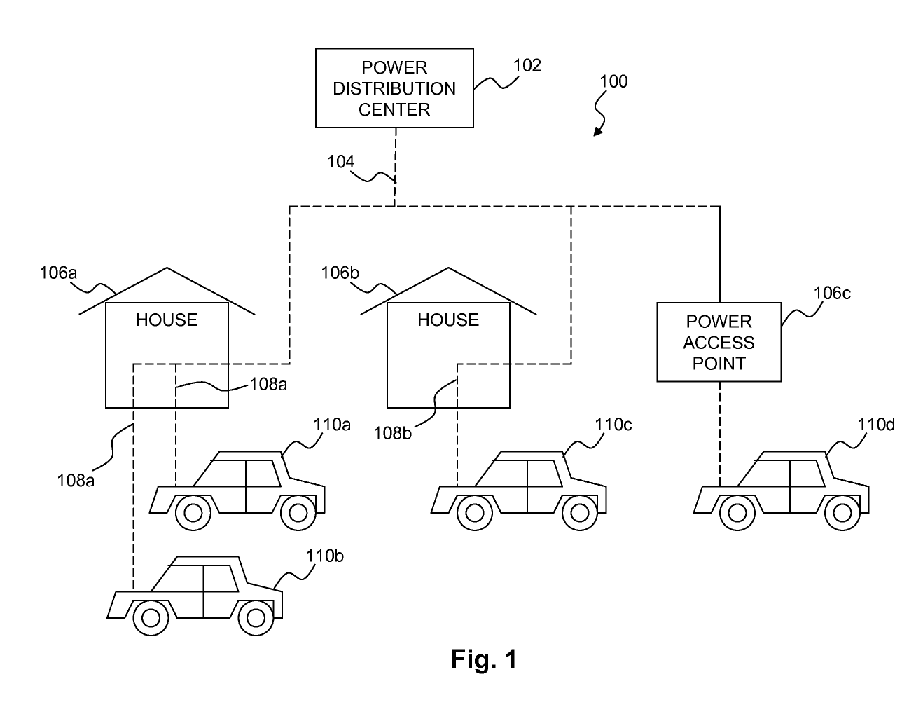

Referring to FIG. 1, in one embodiment, an environment 100 illustrates a power distribution center 102 coupled to a power grid 104. The power distribution center 102 may be a large power source, such as a power station or a substation configured to provide a large amount of electrical power over a relatively large area. Accordingly, the power grid 104 may provide power from the power distribution center 102 to various residential and commercial structures. For purposes of illustration, the power grid 104 couples power access points 106a, 106b, and 106c to the power distribution center 102. In the present example, the power access points 106a and 106b are houses with internal power distribution channels 108a and 108b (e.g., wiring), respectively, while the power access point 106c is a generic power access point that may be privately or publicly accessible. One example of the generic power access point 106c is an electrical outlet at a fueling station or a garage. Some or all of the power access points 106a-106c may also be power consumers, such as the houses 106a and 106b.

A plurality of power consumers 110a-110d may require energy and their energy needs may vary. For purposes of illustration, the power consumers 110a-110d are vehicles (e.g., cars) that frequently (e.g., once a day or once every several days) need electrical power to recharge their batteries. For example, the cars 110a-110d may be electric cars or hybrid gasoline-electric cars that are powered at least partially by one or more batteries, and the batteries may need to be recharged on a fairly regular schedule. It is understood that the amount of recharging (referred to herein as a recharge cycle) needed by a particular one of the cars 110a-110d may depend on many factors, including battery type, battery size, distance driven since last recharge, speed, and ambient temperature. As such, not only may the electrical power needs of each car 110a-110d vary relative to the other cars, but the power needs of each car for a particular recharge cycle may vary relative to other recharge cycles for the same car.

For purposes of illustration, many of the various aspects and embodiments are described in connection with “cars;” however, it will be understood that the invention may be equally applicable in connection with other types of vehicles and equipment equipped with electrical storage batteries. Accordingly, the term “car” as used throughout this disclosure is not limited to cars and automobiles, but may also include other vehicles, including, but not limited to, trucks, tractors, lift trucks, motorcycles, boats, locomotives, and aircraft.

To access the power grid 104, the cars 110a and 110b are coupled to the internal power distribution channel 108a of the house 106a, the car 110c is coupled to the internal power distribution channel 108b of the house 106b, and the car 110d is coupled to the power access point 106c. The coupling may occur by, for example, plugging one end of an electrical cable into an access port (not shown) on each of the cars 110a-110d and plugging the other end of the electrical cable into an outlet (not shown) of the respective power access points 106a-106b. Accordingly, although not shown, cables or other power transfer components may be present in FIG. 1.

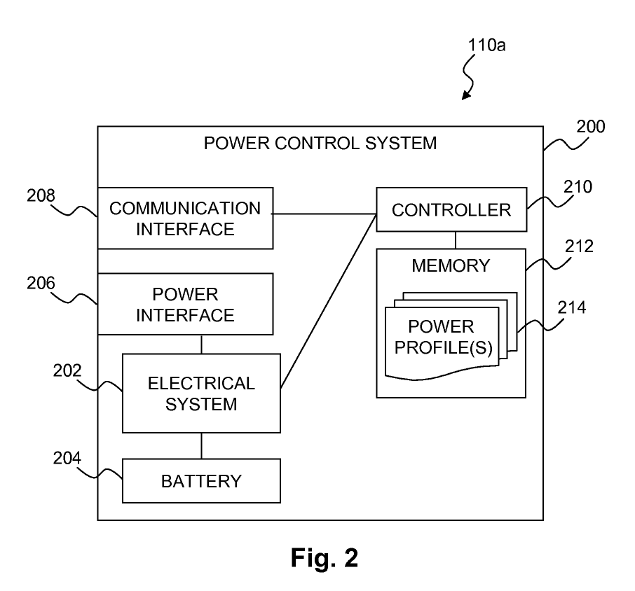

Referring to FIG. 2, one embodiment of a power control system 200 of a power consumer, such as the car 110a of FIG. 1, is illustrated. The power control system 200 includes an electrical system 202 coupled to a battery 204, which may be part of or separate from the electrical system. The battery 204 may be used to provide power to the electrical system 202, which in turn may provide power for various functions of the car 110a, including propulsion. The power control system 200 may include a power interface 206 and a communication interface 208, which may be combined into a single interface in some embodiments. The power interface 206 may be used to couple the power control system 200 to a power source (e.g., the internal power distribution channel 108a of FIG. 1). The communication interface 208 may be used to couple the power system 200 to a power distribution controller, as will be discussed in greater detail below. The communication interface 208 may be configured to send and receive data using one or more technologies, including data transfer over power line technologies (e.g., the internal power distribution channel 108a and grid 104), and wired or wireless (e.g., cell phone or Bluetooth) data transfer over communication networks such as cell networks, packet data networks such as the Internet, and/or satellite links.

A controller 210 may be coupled to the electrical system 202 and to a memory 212. In some embodiments, the controller 210 may include the memory 212. One example of the controller is a VController, such as that described in detail in U.S. patent application Ser. No. 12/134,424, filed on Jun. 6, 2008, and entitled SYSTEM FOR INTEGRATING A PLURALITY OF MODULES USING A POWER/DATA BACKBONE NETWORK, which is incorporated by reference herein in its entirety. The memory 212 may contain one or more power profiles 214 that may be used to manage recharge of the battery 204 and to store information about the electrical system 202 and battery 204. Different power profiles 214 may be stored based on, for example, different users, driving styles (e.g., city or highway), and seasons (e.g., winter or summer).

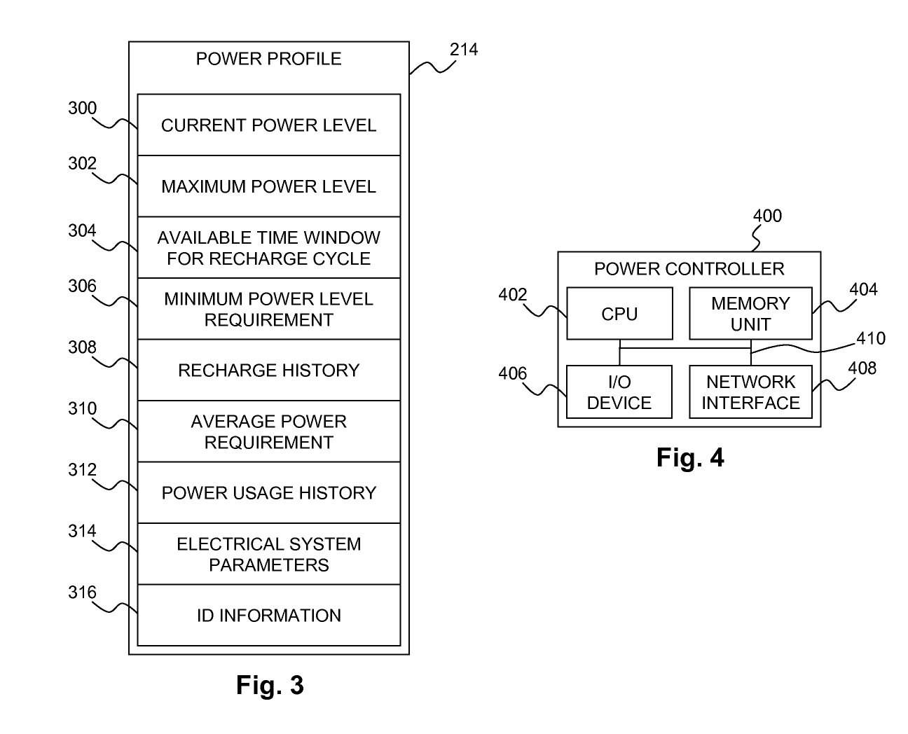

Referring to FIG. 3, one embodiment of the power profile 214 of FIG. 2 is illustrated in greater detail. The power profile 214 may contain information useful in managing the recharge of the battery 204, as well as other information such as technical specifications and performance data of the electrical system 202 and battery 204. The power profile 214 may be maintained by the controller 210 and/or one or more external controllers, such as a controller located in the power distribution center 102 or house 108a. The power profile 214 may be stored in a database format, a plain text format, or any other suitable format used for such data. At least some portions of the power profile 214 may be accessible via a browser in a browser accessible format such as HyperText Markup Language (HTML) or eXtensible Markup Language (XML).

In the present example, the power profile 214 may include a current power level 300, a maximum power level 302, an available time window for a recharge cycle 304, a minimum power level requirement 306, a recharge history 308, an average power requirement 310, a power usage history 312, parameters 314 of the electrical system 202, and identification (ID) information 316. In other embodiments of the power profile 214, various entries may be combined, divided into multiple entries, or omitted entirely. For example, the maximum power level 302 may be one of the electrical system parameters 314, while the recharge history 308 may be subdivided into calendar days or weeks. Furthermore, additional entries not shown in FIG. 3 may be present.

The current power level 300 may indicate a power level of the battery 204 at the time the power profile 214 was stored and may be updated periodically. The maximum power level 302 may indicate a maximum charge for the battery 204 and may be used with the current power level 300 to determine recharge cycle parameters, such as estimated power consumption and time. The available time window for recharge cycle 304 indicates a period of time during which the power control system 200 needs to be recharged. For example, if a user of the car 110a arrives at the house 106a at 7:00 PM and needs to leave the house the next morning at 7:00 AM, the available time window for the recharge cycle would be twelve hours. It is understood that a buffer may be built into the time window (e.g., a thirty minute time period immediately prior to 7:00 AM) to ensure that the recharge cycle is able to complete if interrupted.

The minimum power level requirement 306 may represent a minimum power level needed by the battery 204 to operate from the current recharge cycle until the next recharge cycle. For example, the electrical system 202 may consume an amount of power during a given day that typically falls within a given power range. Accordingly, this may be used to calculate the minimum amount of power that will likely be needed for the following day. A buffer may be included in the calculations to ensure that there will be sufficient power for a certain amount of extra activity.

The recharge history 308 may include information about previous recharges. For example, the information may include recharge times, power consumption, and faults or interruptions. The average power requirement 310 may represent an average amount of power used by the electrical system 202, and may be used with the minimum power level requirement 306. The power usage history 312 may include detailed information on power consumption by the power system 200, such as peak power consumption, driving characteristics (e.g., rapid or slow acceleration), weather variables, and similar information. The electrical system parameters 314 may detail various technical aspects of the electrical system 202, including maximum possible power loads, minimum power requirements, amount of power required by various components and/or subsystems, normal times of operation for various components and/or subsystems (e.g., headlights at night), and similar parameters.

The ID information 316 may represent information identifying the car 110a. Such information may include a unique code assigned by the power distribution center 102 to the car 110a and/or the house 106a, a vehicle identification number (VIN) or license plate number of the car 110a, and/or other information designed to uniquely identify a power consumer. The ID information 316 may also include location information such as an address of the house 106a and/or a location of the car 110a denoted by global positioning system (GPS) coordinates or other location data. Accordingly, the ID information 316 may be used to uniquely identify the car 110a as a particular power consumer and, in some embodiments, may also identify a location of the car 110a in order for the power distribution center 102 to more efficiently allocate power.

Referring to FIG. 4, one embodiment of a power controller 400 is illustrated. The power controller 400 may be located in, for example, one or more of the power access points 106a-106c, the power distribution station 102, and/or a neighborhood power distribution node. The power controller 400 may interact with other controllers 400 and/or the controller 210 of the power control system 200 of FIG. 2. The power controller 400 may include components such as a central processing unit (“CPU”) 402, a memory unit 404, an input/output (“I/O”) device 406, and a network interface 408. The network interface 408 may be, for example, one or more network interface cards (NICs) that are each associated with a media access control (MAC) address. The components 402, 404, 406, and 408 are interconnected by one or more communications links 410 (e.g., a bus).

It is understood that the power controller 400 may be differently configured and that each of the listed components may actually represent several different components that may be distributed. For example, the CPU 402 may actually represent a multi-processor or a distributed processing system; the memory unit 404 may include different levels of cache memory, main memory, hard disks, and remote storage locations; and the I/O device 406 may include monitors, keyboards, and the like. The network interface 408 enables the power controller 400 to connect to a network.

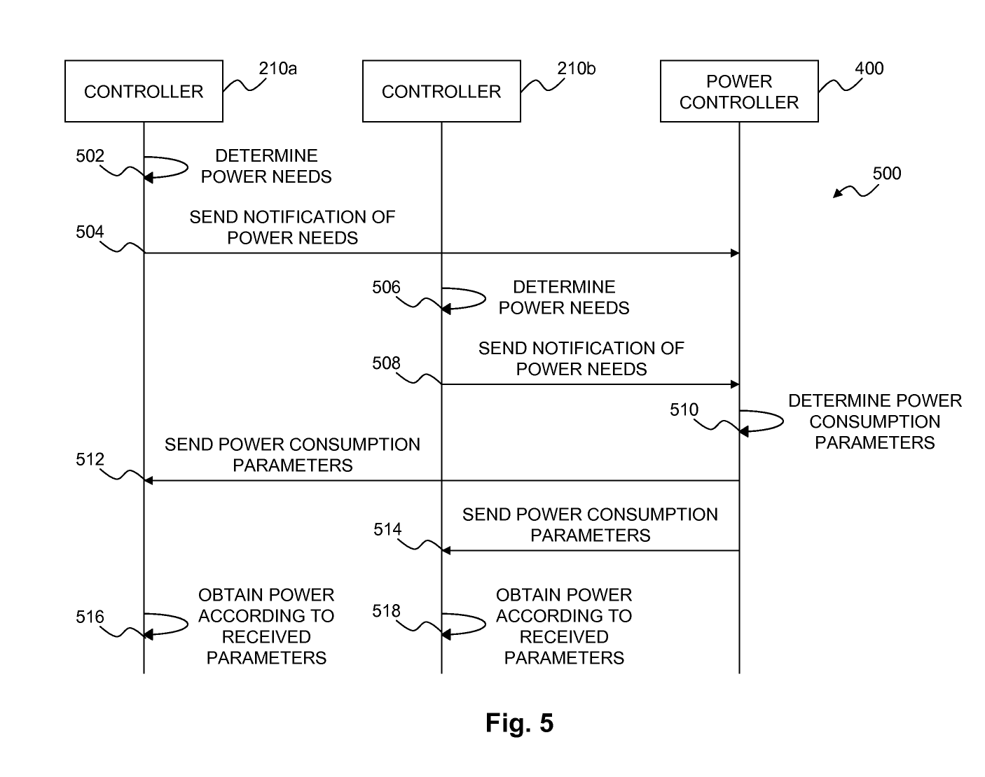

Referring to FIG. 5, in another embodiment, a sequence diagram 500 illustrates one sequence of actions that may occur to schedule battery charging for multiple distributed power consumers. In the present example, the power controller 400 of FIG. 4 is located in the power distribution center 102 of FIG. 1 and is in communication with multiple controllers 212 of FIG. 2 (designated 212a, 212b in FIG. 5), which are located in the cars 110a and 110c, respectively.

In step 502, the controller 210a determines the power needs of the battery 204 of the car 110a and, in step 504, sends a notification message to inform the power controller 400 of the determined power needs. In step 506, the controller 210b determines the power needs of the battery 204 of the car 110c and, in step 508, sends a notification message to inform the power controller 400 of the determined power needs. The sending may occur over the grid 104 (e.g., using data transfer over power line technology), over a wired or wireless connection via a packet data network such as the Internet, and/or over a satellite or other communication system, such as an emergency communication system installed in a car.

The notification messages sent in steps 504 and 508 may or may not include power profiles 214. In step 510, the power controller 400 determines power consumption parameters for each of the cars 110a and 110c. This determination may use the power profile 214 and/or other information received from the controllers 210a and 210b to schedule power consumption times and/or power bandwidth (e.g., a maximum power draw) for each of the cars 110a and 110c.

In some embodiments, the power controller 400 may balance general power consumption information for the grid 204 with the needs of each of the cars 110a, 110c, and/or other power consumers to create a customized power consumption schedule for each car. It is understood that the determination of step 510 may occur frequently (e.g., each time the controllers 210a and 210b are coupled to the grid 104) or may occur on a periodic basis (e.g., at daily or weekly intervals). For example, the power controller 400 may make the determination for a particular power consumer once a week and the power consumer may then follow that power consumption schedule for that week. Alternatively, the power consumer may follow a power consumption schedule until another one is received, regardless of the amount of time that passes from the receipt of the current schedule. An extended power schedule that lasts a week or more may use cumulative power consumption information to determine average power consumption needs for each day. For example, the car 110a may typically use eighty percent of the battery power on weekdays, but only forty-five percent on weekends. This information may be used to create the power consumption schedule.

In other embodiments, the power controller 400 may assign each of the cars 110a and 110c to a predefined power consumption class that in turn defines the power consumption parameters for the power consumers in that class. For example, a class may define a starting power consumption time of 2:00 AM and an ending power consumption time of 6:00 AM. The class may also define a maximum power bandwidth. Accordingly, power consumers assigned to that class may begin power consumption at 2:00 AM and continue until 6:00 AM, and they may draw a maximum amount of power as defined by the power bandwidth. The use of power consumption classes enables the power controller 400 to perform power load balancing without the need to define customized power consumption parameters for each power consumer. Power profiles 214 sent by the cars 110a and 110c may be used to identify the class into which each car should be placed. For example, the power controller 400 may assign the car 110a to a first class that allows power consumption from 10:00 PM until 2:00 AM and may assign the car 110c to a second class that allows power consumption from 2:00 AM until 6:00 AM. This may be particularly useful for houses that have multiple cars, such as the house 106a with cars 110a and 110b, as the power controller 400 can stagger the charging times to minimize the peak power consumption of the house.

In various embodiments, users of the cars 110a and 110c may be able to override the assigned power consumption schedule. For example, the car 110a may typically use only forty-five percent of the battery power on Saturday and so the power consumption schedule may be based on this use. However, one weekend, the user of the car 110a plans to leave town for the weekend and therefore will use much more of the battery's available power. Accordingly, the user may override the power consumption schedule to ensure that the battery is fully charged for Saturday.

In steps 512 and 514, the power controller 400 sends the determined power consumption parameters to the controllers 210a and 210b, respectively. This may be in the form of an updated power profile 214 for each of the controllers 210a and 210b, or may be information that the controllers use to update their corresponding power profiles. In steps 516 and 518, respectively, the controllers 210a and 210b use the received parameters to regulate the charging of their respective batteries 204.

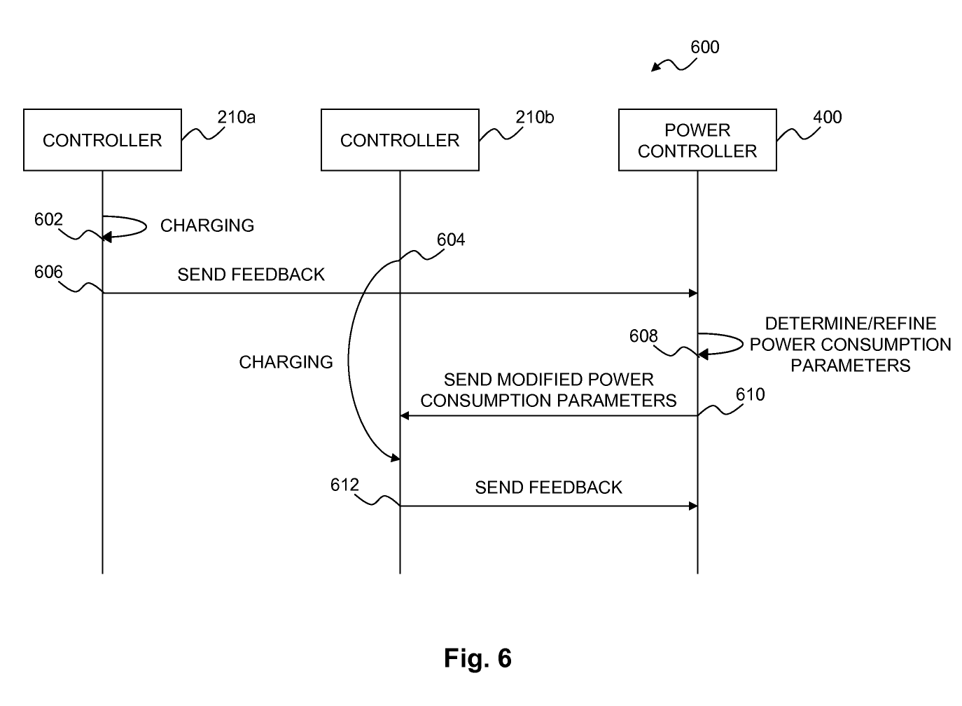

Referring to FIG. 6, in yet another embodiment, a sequence diagram 600 illustrates one sequence of actions that may occur to provide feedback during or after battery charging in an environment with multiple distributed power consumers. In the present example, power controller 400 is the power controller 400 of FIG. 4 and is located in the power distribution center 102 of FIG. 1. The power controller 400 is in communication with multiple controllers 212 of FIG. 2 (designated 212a, 212b in FIG. 5), which may be located in the cars 110a and 110c, respectively.

Although the sequence diagram 600 begins with controllers 210a and 210b managing a charging process for their respective cars 110a and 110c in steps 602 and 604, it is understood that other steps may precede steps 602 and 604. For example, steps 502-514 of FIG. 5 may have already occurred. Furthermore, it is understood that the charging processes represented by steps 602 and 604 may overlap.

In step 606, the charging process managed by controller 210a has ended and the controller 210a sends feedback information to the power controller 400 about the charging process. For example, the feedback information may indicate that the charging process is complete and may notify the power controller 400 of various charging information, such as start time, stop time, average power draw, and peak power draw. The power controller 400 may use this information to determine power consumption parameters or refine existing power consumption parameters in step 608. The power controller 400 may then send modified power consumption parameters to the controller 210b in step 610. For example, the power controller 400 may determine in step 608 that additional power is available for controller 210b and may notify the controller 210b in step 610 that it can increase its power bandwidth. The controller 210b may then dynamically adjust its power bandwidth during the recharge cycle to compensate for the modified power consumption parameters. This adjustment may occur dynamically during the charging process.

In step 612, when the charging process managed by controller 210b has ended, the controller 210b may send feedback information to the power controller 400 about the charging process as described with respect to step 606. Accordingly, using feedback information received from power consumers, the power controller 400 may dynamically allocate power more efficiently. Although not shown, the power controller 400 may update the power consumption parameters for cars that have not yet started their recharge cycles (e.g., the cars 110b and 110d) to dynamically adjust to increases and decreases in power demands on the grid 104.

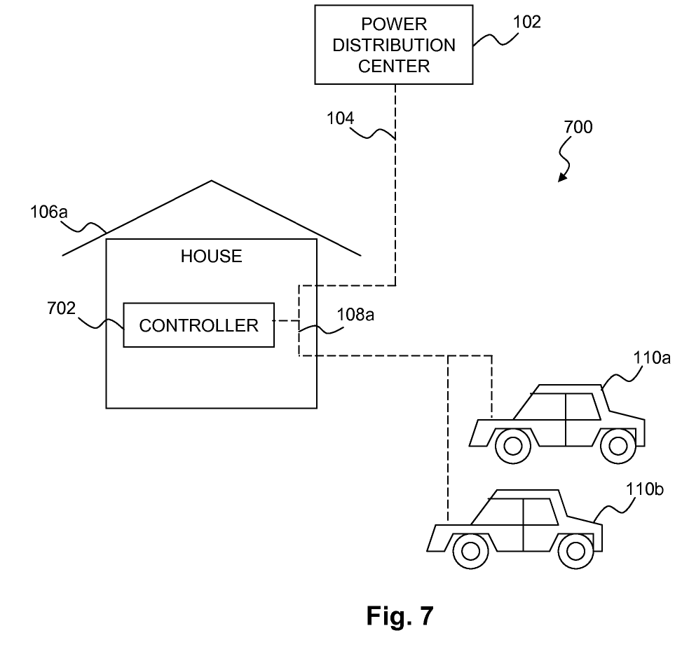

Referring to FIG. 7, in another embodiment, an environment 700 is illustrated in which information relative to power consumption by a power access point/power consumer (e.g., the house 106a) may be sent to the power controller 400. For example, a controller 702 (which may be similar or identical to the power controller 400 of FIG. 4) located in the house 106a may communicate with the cars 110a and 110b to obtain information regarding the power needs of each of the cars. The controller 702 may also obtain information regarding the power needs of various components and/or subsystems of the house 106a itself, such as heating and air conditioning units, electronic equipment, and lighting. As the power needs of the house 106a may vary depending on the time of day and the external temperature, the controller 702 may create or maintain a profile of the house's power consumption. This profile may contain information such as that previously described with respect to the profile 214 of FIG. 3, although containing information suitable for a house or other structure rather than a car.

The controller 702 may send the information obtained from the cars 110a and 110b to the power controller 400 either with the information of the house 106a or separately. If sent together, the controller 702 may include the power needs of the cars 110a and 110b in the profile of the house 106a, and may list the cars as components or subsystems of the house. In other embodiments, the cars 110a and 110b may send their information to the power controller 400 without notifying the controller 702, and the power controller 400 may aggregate the information to determine the energy needs of the house 106a and the corresponding cars 110a and 110b.

In another embodiment, power consumption schedules provided by the power distribution center 102 of FIG. 1 may provide cost benefits if followed by power consumers. In such embodiments, power consumption schedules may not be imposed by the power distribution center 102, but may be optional. For example, the controller 702 (FIG. 7) of the house 106a may receive a power consumption schedule from the power controller 400 of the power distribution center 102. If the controller 702 follows the power consumption schedule by regulating the power consumption of the cars 110a and 110b, as well as other components/subsystems of the house 106a, the power distribution center 102 may calculate or apply a predetermined discount to some or all of the electricity consumed by the house. The power distribution center 102 may monitor a usage level of the house 106a or may verify the usage level during the scheduled timeframe to ensure that the discount should be applied. In other embodiments, the cars 110a and 110b may send information to the power controller 400 and/or 702 to report their energy consumption in order to receive discounted power rates.

Tiered service may also be implemented, with additional power bandwidth and/or longer or specific times being available for an additional price. In such tiered service embodiments, electricity consumed while following the power consumption plan may be billed at a normal or discounted rate, while deviations from the power consumption plan (e.g., beginning prior to the start time) may be billed at a higher rate. This would enable power consumers with special or urgent power requirements to obtain the needed power at a higher cost while not affecting other power consumers, although the other power consumers' may receive modified power consumption plans as the power controller 400 balances the load on the grid 104.

In still other embodiments, a car such as the car 110a of FIG. 1 may report its energy needs to the power controller 400 and/or controller 702 before being coupled to the grid 104. For example, the controller 210 of FIG. 2 may determine or estimate its energy needs at a specific time or when its battery falls below a defined charge level. The controller 210 may then report its energy needs via the communication interface 208 using a wireless communication channel. This information may be used by the power controller 400 to plan for later energy consumption by the car 110a. In some embodiments, the power controller 400 may reward such early reporting by applying a discounted rate to the power consumed by the car 110a if, for example, the estimated power needs communicated by the controller 210 are relatively close to the power actually consumed.

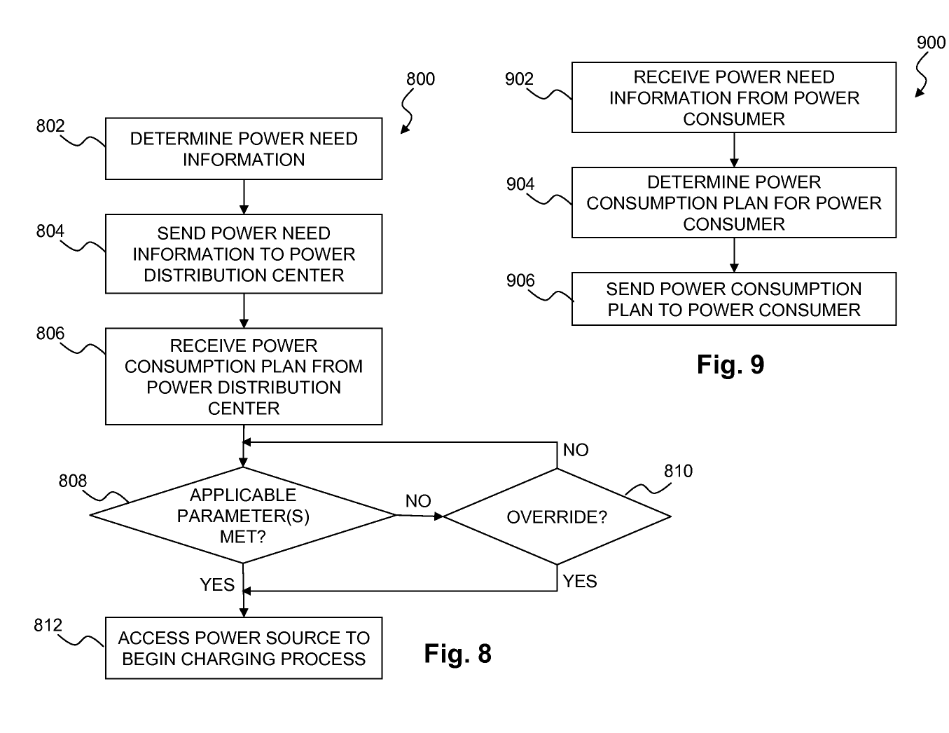

Referring to FIG. 8, one embodiment of a method 800 is illustrated. The method 800 may be used by a power consumer to obtain one or more power consumption parameters. In step 802, the power consumer determines power need information. The power need information may include an amount of power required and a time window during which the power is needed. For example, the car 110a may need a certain amount of power to charge its battery 204 (FIG. 4) between 11:00 PM and 6:00 AM. In step 804, the power need information is sent to a power controller in a power distribution center, such as the power controller 400 (FIG. 4) of power distribution center 102. In other embodiments, the power need information may be sent to an intermediate controller (e.g., controller 702 of FIG. 7 in house 106a) and the intermediate controller may then send the power need information to the power controller.

In step 806, a power consumption plan is received from the power distribution center 102. The power consumption plan may include parameters such as a time window during which power is to be drawn from the power grid 104 by the car 110a and a power bandwidth that defines a peak amount of power that may be obtained. In step 808, a determination may be made as to whether one or more of the parameters in the power distribution plan have been met. For example, if a time window is defined by the parameters in the power distribution plan, the determination may compare a current time with the start time of the time window. The power consumption plan may define any number of parameters that make initiation of a charging process conditional. If the conditional parameters are met, the method 800 moves to step 812, where the car 110a accesses a power source coupled to the power grid 104 to begin the charging process. If no such conditional parameters are in the power consumption plan, the method 800 continues to step 812.

If conditional parameters are present in the power consumption plan and not met as determined in step 808, the method 800 moves to step 810. In step 810, a determination is made as to whether there is an override in place for the car 110a. The override may indicate that the power consumption plan is to be ignored or that only certain aspects of the power consumption plan are to be followed. For example, the override may ignore all parameters, may comply with the time window while ignoring the power bandwidth parameter, or may comply with the power bandwidth parameter while ignoring the time window. Accordingly, in some embodiments, the override may be customizable as desired.

If it is determined in step 810 that there is no override, the method 800 returns to step 808. Steps 808 and 810 may be repeated until the conditional parameters are met or there is an override. It is understood that the method 800 may have additional steps, such as a timeout or an alert to prevent steps 808 and 810 from looping indefinitely. If it is determined in step 810 that there is an override, the method 800 may continue to step 812 to begin the charging process.

Although shown only in step 810, the override may be applicable to step 812 as well. For example, if the override corresponds to a conditional parameter such as the start time, the override may be used to bypass step 808 (assuming that any other conditional parameters are met or have overrides). However, if the override corresponds only to a non-conditional parameter such as the power bandwidth, the override will not bypass step 808. Accordingly, the conditional parameter must still be met, and the override will then apply to the power bandwidth only after the conditional parameter of the start time has been satisfied.

Referring to FIG. 9, one embodiment of a method 900 is illustrated. The method 900 may be used by a power controller (e.g., the power controller 400 of FIG. 4) to manage power consumption by a power consumer, such as the car 110a of FIG. 1. In step 902, the power controller 400 receives power need information from the car 110a. The power need information may include an amount of power required and a time window during which the power is needed. For example, the car 110a may need a certain amount of power to charge its battery 204 (FIG. 4) between 11:00 PM and 6:00 AM. The power need information may also include technical information, such as an ideal power draw for the battery 204.

In step 904, the power controller 400 determines a power consumption plan for the car 110a. The power consumption plan may include parameters such as a time window during which power is to be drawn from the power grid 104 by the car 110a and a power bandwidth that defines a peak amount of power that may be obtained. The power consumption plan may be calculated in light of many other consumers' power needs to ensure that the grid is capable of providing the requested power. In step 906, the power consumption plan may be sent to the car 110a, either directly or via another controller, such as the controller 702 of FIG. 7.

The present disclosure describes managing the distribution of power to cars and other automotive vehicles across an electrical grid. However, it is understood that the present disclosure may be applied to both vehicles and structures. Accordingly, the term “vehicle” may include any artificial mechanical or electromechanical system capable of movement (e.g., motorcycles, cars, trucks, boats, and aircraft), while the term “structure” may include any artificial system that is not capable of movement. Although both a vehicle and a structure are used in the present disclosure for purposes of example, it is understood that the teachings of the disclosure may be applied to many different environments and variations within a particular environment. Accordingly, the present disclosure may be applied to vehicles and structures in land environments, including manned and remotely controlled land vehicles, as well as above ground and underground structures. The present disclosure may also be applied to vehicles and structures in marine environments, including ships and other manned and remotely controlled vehicles and stationary structures (e.g., oil platforms and submersed research facilities) designed for use on or under water. The present disclosure may also be applied to vehicles and structures in aerospace environments, including manned and remotely controlled aircraft, spacecraft, and satellites.

It should be understood that the drawings and detailed description herein are to be regarded in an illustrative rather than a restrictive manner, and are not intended to be limiting to the particular forms and examples disclosed. On the contrary, included are any further modifications, changes, rearrangements, substitutions, alternatives, design choices, and embodiments apparent to those of ordinary skill in the art, without departing from the spirit and scope hereof, as defined by the following claims. Thus, it is intended that the following claims be interpreted to embrace all such further modifications, changes, rearrangements, substitutions, alternatives, design choices, and embodiments.

What is claimed is:

1. A power control system positioned within a car comprising:
an electrical system;
a battery coupled to the electrical system;
a power interface coupled to the electrical system;
a communication interface;
a controller coupled to the electrical system and the communication interface; and
a memory coupled to the controller and containing a plurality of instructions executable by the controller, the instructions including instructions for:
receiving at least one power consumption parameter from a power controller external to the car via the communication interface;
actuating the electrical system to access an external power source via the power interface; and
directing power from the power source to the battery via the electrical system in order to charge the battery, wherein at least one of actuating the electrical system to access the external power source and an amount of power directed to the battery is based on the at least one power consumption parameter.

2. The power control system of claim 1 wherein the instructions further comprise instructions for determining a charge level of the battery while power is being directed from the external power source to the battery.

3. The power control system of claim 1 further comprising a power profile stored in the memory, wherein the power profile includes information about power usage by the car.

4. The power control system of claim 3 wherein the at least one power consumption parameter is stored by the controller as part of the power profile.

5. The power control system of claim 1 further comprising a power profile stored in the memory, wherein the power profile includes information about at least one power need of the car that is based on an amount of power needed by the battery.

6. The power control system of claim 5 wherein the power profile further includes information defining a time window during which the car is available to access the external power source.

7. The power control system of claim 6 further comprising instructions for sending the information about the at least one power need and the time window to the power controller via the communication interface.

8. The power control system of claim 7 wherein the sending occurs after the car is coupled to the external power source.

9. The power control system of claim 7 wherein the sending occurs before the car is coupled to the external power source.

10. The power control system of claim 1 wherein the at least one power consumption parameter defines a start time representing an earliest time at which the car is to access the external power source.

11. The power control system of claim 10 wherein the at least one power consumption parameter further defines an end time representing a latest time at which the car is to access the external power source.

12. The power control system of claim 1 wherein the at least one power consumption parameter further defines a power bandwidth representing a peak power draw to be used by the car when accessing the external power source.

13. The power control system of claim 1 further comprising instructions for sending a compliance notification via the communication interface, wherein the compliance notification confirms that the battery was charged based on the at least one power consumption parameter.

14. The power control system of claim 1 further comprising instructions for sending a notification to the power controller that the car has finished charging.

15. The power control system of claim 1 further comprising instructions for overriding the at least one power consumption parameter.

16. The power control system of claim 1 further comprising instructions for sending identification information to the power controller, wherein the identification information represents at least one of a unique identity and a location of the car.

17. A power controller for managing power consumption by a car coupled to a power grid comprising:
a communication interface;
a processor coupled to the communication interface;
a memory coupled to the processor and containing a plurality of instructions executable by the processor, the instructions including instructions for:
receiving power need information from the car, wherein the power need information identifies an amount of power needed in charging a battery of the car;
identifying a power consumption need for each of a plurality of power consumers;
determining a power consumption plan defining at least one of a start time and a power bandwidth for the car in response to receiving the power need information, wherein at least one of the start time and the power bandwidth is calculated based on the power need information of the car and the power consumption needs of the plurality of power consumers; and
sending the power consumption plan to the car to manage the car's power consumption from the grid.

18. The power controller of claim 17 wherein receiving the power need information from the car includes receiving at least a portion of a profile defining power usage requirements of the car.

19. The power controller of claim 17 wherein receiving the power need information from the car includes receiving at least a portion of a profile defining a power usage history of the car.

20. The power controller of claim 17 wherein receiving the power need information from the car includes receiving a start time and an end time, wherein the start time and end time define an earliest time and a latest time, respectively, that the car is available for power consumption from the grid.

21. The power controller of claim 17 further comprising instructions for determining that the car has complied with the power consumption plan.

22. The power controller of claim 21 further comprising applying a discounted rate to electricity supplied to the car via the grid after determining that the car has complied with the power consumption plan.

23. A method for use in a car comprising:
determining power need information of a battery of the car;
sending the power need information to a power controller external to the car;
receiving a power consumption plan from the power controller, wherein the power consumption plan defines at least one of a start time parameter and a power bandwidth parameter for use in charging the battery;
determining whether an override is active; and
accessing a power source to charge the battery based on the power consumption plan unless the override is active, wherein the override negates at least a portion of the power consumption plan.
